(19) United States
(12) Patent Application Publication
(10) Pub. No.: US 2012/0241185 A1
(43) Pub. Date: Sep. 27, 2012

(54) ELECTRONIC DEVICE HOUSING AND METHOD OF MANUFACTURING THE SAME

(75) Inventors: MU-CHI HSU, Tu-Cheng (TW); SHAO-MING FU, Tu-Cheng (TW)

(73) Assignee: HON HAI PRECISION INDUSTRY CO., LTD., Tu-Cheng (TW)

(21) Appl. No.: 13/288,169

(22) Filed: Nov. 3, 2011

(30) Foreign Application Priority Data
Mar. 24, 2011 (TW) 100109997

(51) Int. Cl. H05K 5/00; B32B 37/12

(52) U.S. Cl. 174/50; 156/275.5

(57) ABSTRACT

An electronic device housing includes a bottom layer, a adhesion layer and a protection layer. The adhesion layer is located on the bottom layer. The protection layer is located on the adhesion layer. The electronic device housing has excellent appearance and high durability. The present disclosure also provides a method of manufacturing the electronic device housing.

### BACKGROUND

1. Technical Field

The present disclosure relates to a housing, and particularly, to an electronic device housing and a method of forming the housing.

2. Description of Related Art

Conventional housings for consumer electronic devices, such as mobile phones or tablet computers, are usually plastic and made by injection molding. To achieve their designed appearance, the injected housings are usually painted with a spray process. The paint is sprayed from a nozzle of a spray gun and is carried by high-speed air provided from the spray gun onto the housings. Since both the paint and air are sprayed with a high-pressure, the nozzle must be far enough away from the injected housings, or else the high-speed air undesirably blows the paint just coated on the housings away. Thus, a nozzle that is spraying too close can lead to uneven coatings on the housing. However, since a certain distance is kept to lower the spray speed onto the housings, about 70% to 90% of the paint does not reach the housings and is thus wasted. Thus, the conventional painting process is not environmentally friendly.

On the other hand, although plastic housings are easily formed, the visual texture and the touch of plastic housings seems cheap to users, and do not appear as high-class products. In order to improve the texture of the product housings, some housings are made of metal. The metal housings may be polished to provide a brighter and smoother surface. Although the metal texture is popular with users, the surface easily gets scratched due to poor hardness of the metal. The longer the electronics are used, the more the metal housings get scratched, and this leads to an unattractive appearance.

Accordingly, it is desirable to provide an electronic device housing and a method of forming the housing which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a schematic, partial view of an electronic device housing according to a first embodiment of the present disclosure.

FIG. 2 is an exploded view of the electronic device housing of FIG. 1.

FIG. 3 is a cross section view of the electronic device housing of FIG. 1, taken along a cross line III-III.

FIG. 4 is a flowchart of a method of forming the electronic device housing of FIG. 1.

FIG. 5 is a partial, cross section view of an electronic device housing according to a second embodiment of the present disclosure.

FIG. 6 is a schematic, partial view of an electronic device housing according to a third embodiment of the present disclosure.

### DETAILED DESCRIPTION

Embodiments of the disclosure are now described in detail with reference to the accompanying drawings.

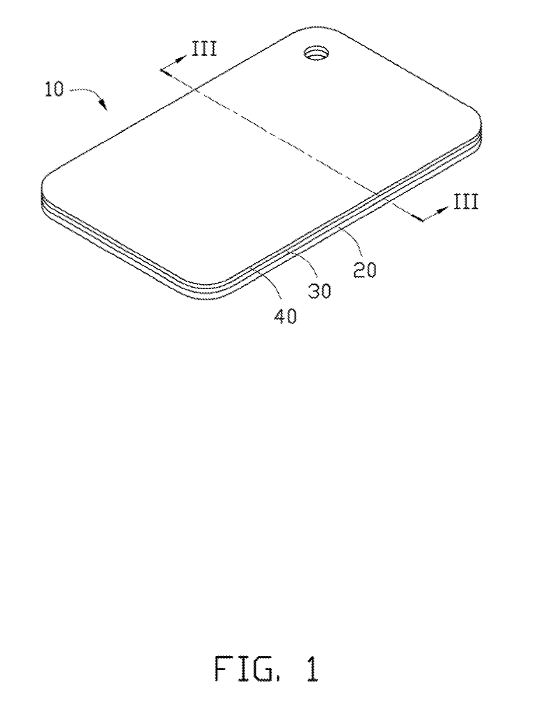

As shown in FIG. 1, the electronic device housing 10 of the present disclosure includes a bottom layer 20, an adhesion layer 30 and a protection layer 40. The adhesion layer 30 is located between the bottom layer 20 and the protection layer 40. In this embodiment, the electronic device housing 10 is a back cover of a mobile phone.

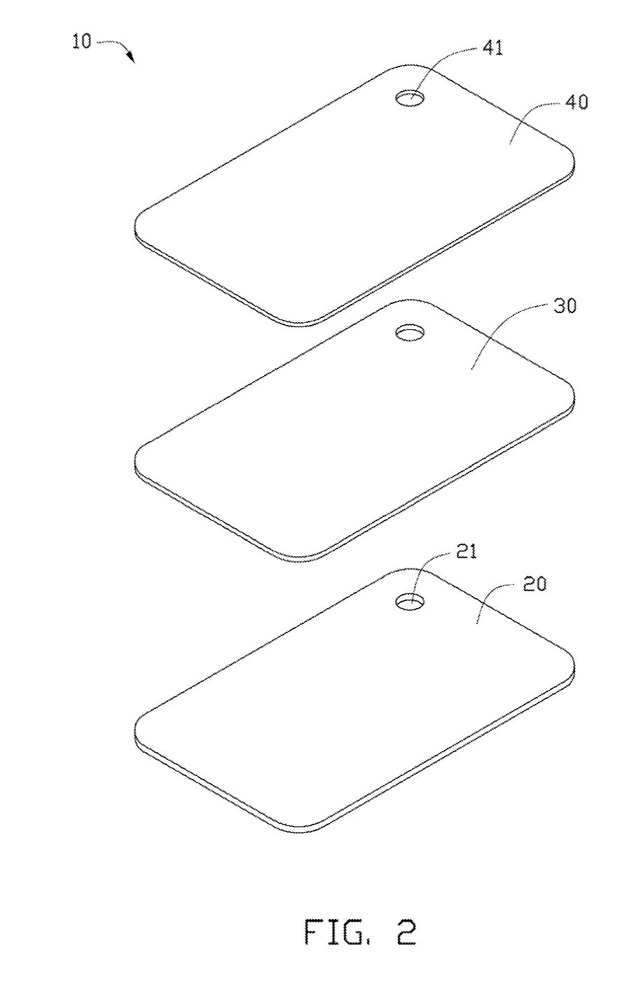

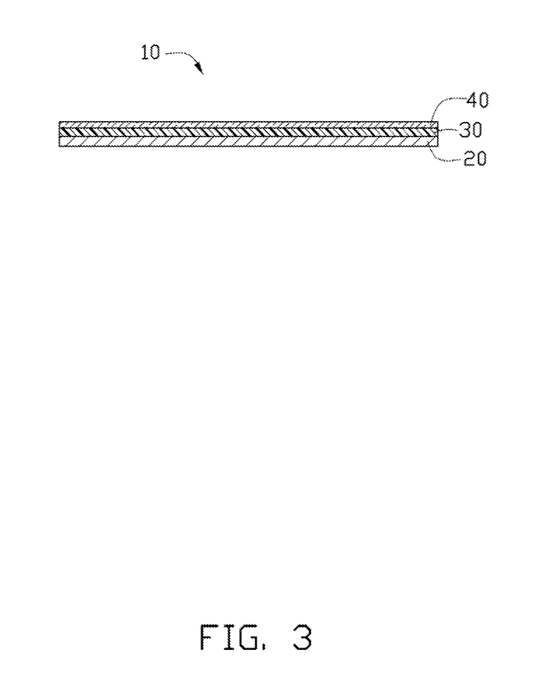

As shown in FIG. 2 and FIG. 3, the bottom layer 20 is located below. The bottom layer 20 covers and protects electronic components of an electronic device, such as circuits and a battery of a mobile phone (not shown), so the electronic components are no longer exposed. In this embodiment, the bottom layer 20 is made from metal, such as stainless steel or aluminum alloy. The bottom layer 20 may be pretreated by one or more surface treatments, such as a polishing process, an etching process or an electroplating process.

The bottom layer 20 defines a through hole 21 corresponding to a camera module (not shown). The camera module may be located in the through hole 21, or behind the through hole 21.

The adhesion layer 30 covers the outer surface of the bottom layer 20, which is the surface users can see, opposite to the electronic components of the electronic device. The adhesion layer 30 is an UV curable adhesive, and is transparent after being cured. In the descriptions, the outer surface or outer side is the portion facing out, and is the upper direction in FIG. 1 through FIG. 3.

The protection layer 40 is located on the adhesion layer 30, opposite to the bottom layer 20. Accordingly, the adhesion layer 30 is sandwiched between the protection layer 40 and the bottom layer 20. The adhesion layer 30 is cured by ultraviolet (UV) rays to tightly combine the bottom layer 20 and the protection layer 40.

In this embodiment, the protection layer 40 is transparent glass defining a through hole 41 corresponding to the camera module (not shown). The camera module may be located in the through hole 41, or behind the through hole 41.

The bottom layer 20 is protected by the protection layer 40, and therefore cannot be scratched or defaced. Accordingly, the visible surface of the bottom layer 20 can be kept bright and smooth, and the electronic device housing 10 has metallic luster on the bottom layer 20.

The glass protection layer 40 is harder than the bottom layer 20, so it is harder to scratch the electronic device housing 10, and the appearance of the electronic device housing 10 can be kept new and glossy.

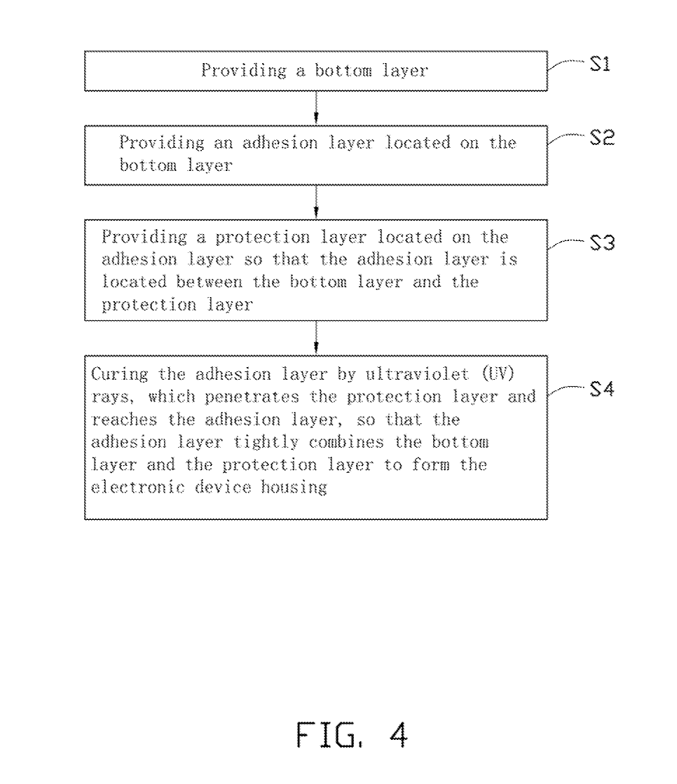

As shown in FIG. 4, a method of forming an electronic device housing includes steps of providing a bottom layer 20 in step S1. Providing an adhesion layer 30 located on the bottom layer 20 in step S2; providing a protection layer 40 located on the adhesion layer 30 in step S3 so that the adhesion layer 30 is located between the bottom layer 20 and the protection layer 40. In addition, in step S4, cures the adhesion layer 30 with UV rays, which penetrates the protection layer 40 and reaches the adhesion layer 30. The adhesion layer 30 tightly combines the bottom layer 20 and the protection layer 40 to form the electronic device housing 10.

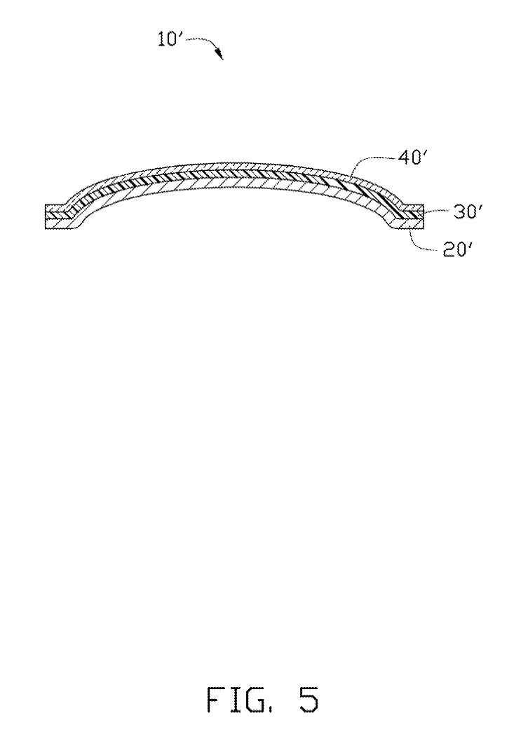

FIG. 5 illustrates a second embodiment of the present disclosure. The second embodiment is similar to the first embodiment, but has a different shape. The outline of the bottom layer 20′ is not a flat plate, and the outer surface of the bottom layer 20′ is a non-plane surface, such as a curved surface. The inner surfaces of the adhesion layer 30′ and the protection layer 40′ match the curved surface of the bottom layer 20′. The inner surface of the adhesion layer 30′ is the surface contacting the bottom layer 20′, and the inner surface of the protection layer 40′ is the surface contacting the adhesion layer 30′. Accordingly, the electronic device housing 10′ can have a curved outer surface, a streamline outer surface, or any designed shape in the present disclosure.

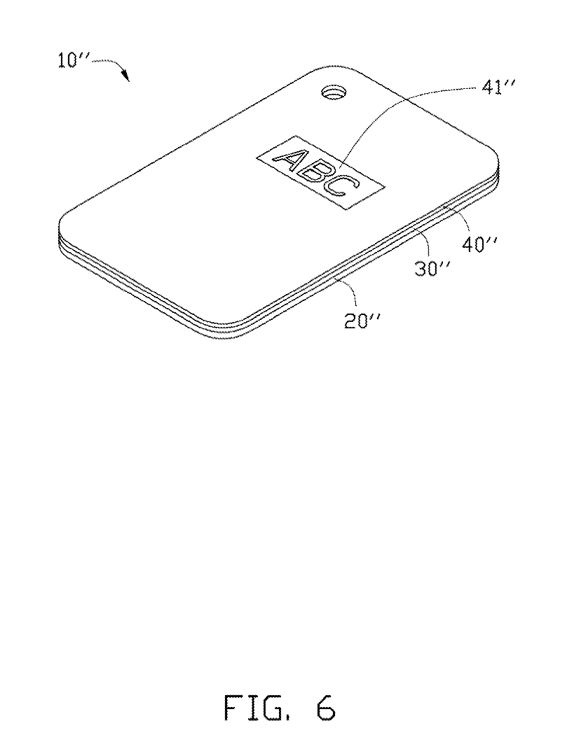

FIG. 6 illustrates a third embodiment of the present disclosure. The third embodiment is similar to the first embodiment, but with a different nameplate 41″. The electronic device housing 10″ of the third embodiment further includes a nameplate 41″ inserted into the protection layer 40″. The nameplate 41″ may bear a name, a trademark, a brand, or any design.

It is to be understood, however, that even though numerous characteristics and advantages of the present embodiments have been set fourth in the foregoing description, together with details of the structures and functions of the embodiments, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. An electronic device housing, comprising:
a bottom layer;
an adhesion layer located on the bottom layer; and
a protection layer located on the adhesion layer, wherein the adhesion layer is cured by ultraviolet (UV) rays to tightly combine the bottom layer and the protection layer.

2. The electronic device housing of claim 1, wherein the bottom layer is selected from the group consisting of stainless steel and aluminum alloy.

3. The electronic device housing of claim 2, wherein the bottom layer is pretreated by a surface treatment.

4. The electronic device housing of claim 1, wherein the protection layer is glass.

5. The electronic device housing of claim 4, wherein the glass is transparent.

6. The electronic device housing of claim 1, wherein the adhesion layer is an UV curable adhesive.

7. The electronic device housing of claim 1, wherein the bottom layer comprises a non-plane surface.

8. The electronic device housing of claim 7, wherein the adhesion layer comprises an inner surface matching and contacting the non-plane surface of the bottom layer.

9. The electronic device housing of claim 7, wherein the protection layer comprises an inner surface matching the non-plane surface of the bottom layer and contacting the adhesion layer.

10. The electronic device housing of claim 1, wherein the bottom layer defines a through hole corresponding to a camera module.

11. The electronic device housing of claim 1, further comprising a nameplate inserted into the protection layer.

12. A method of forming an electronic device housing, comprising:
providing a bottom layer;
providing an adhesion layer located on the bottom layer;
providing a protection layer located on the adhesion layer so that the adhesion layer is located between the bottom layer and the protection layer;
curing the adhesion layer by ultraviolet (UV) rays, which penetrates the protection layer and reaches the adhesion layer, so that the adhesion layer tightly combines the bottom layer and the protection layer to form the electronic device housing.

13. The method of claim 12, wherein the bottom layer is selected from a group consisting of stainless steel and aluminum alloy.

14. The method of claim 13, wherein the bottom layer is pretreated by a surface treatment.

15. The method of claim 12, wherein the protection layer is glass.

16. The method of claim 15, wherein the glass is transparent.

17. The method of claim 12, wherein the adhesion layer is an UV curable adhesive.

18. The method of claim 12, wherein the bottom layer comprises a non-plane surface.

19. The method of claim 18, wherein the adhesion layer comprises an inner surface matching and contacting the non-plane surface of the bottom layer.

20. The method of claim 18, wherein the protection layer comprises an inner surface matching the non-plane surface of the bottom layer and contacting the adhesion layer.
